(19) United States
(12) Patent Application Publication
(10) Pub. No.: US 2006/0231239 A1
(43) Pub. Date: Oct. 19, 2006

(54) Battery cooler

(76) Inventors: Steffen Katzenberger, Bad Liebenzell (DE); Jochen Bertsch, Muehlacker-Grossglattbach (DE)

Correspondence Address: STRIKER, STRIKER & STENBY, 103 EAST NECK ROAD, HUNTINGTON, NY, 11743, US

(21) Appl. No.: 11/402,156

(22) Filed: Apr. 11, 2006

(30) Foreign Application Priority Data
Apr. 13, 2005 (DE) 10 2005 017057.9

(51) Int. Cl. H01L 23/467; F28F 7/00

(52) U.S. Cl. 165/121; 165/80.3

(57) ABSTRACT

A battery cooler has a flow guidance unit, that includes at least one pressure conduit; and also a hand power tool, a charger and a hybrid drive unit are provided with such battery cooler.

### BACKGROUND OF THE INVENTION

The present invention relates in particular to a battery cooler.

Japanese Patent Disclosure JP 08185898 A, for cooling an arrangement of accumulators, proposes locating them in a housing, monitoring the temperature in the housing, and using a fan actively for cooling. The fan aspirates air from the housing, creating a negative pressure in the housing. As a consequence, cool outside air flows through existing air inlets, which form a flow guidance unit, into the housing and cools the accumulators.

### SUMMARY OF THE INVENTION

It is therefore an object of the present invention to provide a battery cooler which is a further improvement of the existing battery coolers.

In keeping with these objects and with others which will become apparent hereinafter, one feature of the present invention resides, briefly stated, in a battery cooler having a flow guidance unit, in which the flow guidance unit include at least one pressure conduit.

The term “pressure conduit” is understood to mean in particular a conduit which has a special sealing or sealing means for the buildup of a pressure, advantageously a pressure of more than 100 mbar and especially advantageously a pressure of more than 200 mbar and especially preferably a pressure of between 300 mbar and 600 mbar, and/or is intended for connection to a pressure vessel and/or in particular to a pump. The term “battery” should be understood in this context to mean both a nonrechargeable and in particular a rechargeable storage unit.

By means of the provisions of the invention, an especially advantageous cooling can be achieved for especially tightly packed battery units that have high flow resistances, and in particular, a temperature distribution that is advantageously at least largely uniform, can be achieved inside a corresponding battery unit.

The battery cooler can in principle include a closed cooling system, so that a cooling medium can circulate within a closed system. However, especially advantageously, the battery cooler has an open cooling system, in which a cooling medium, after absorbing heat, can give it up to the environment, and as a result the cooling system can be implemented especially economically and structurally simply.

As a pressure medium or cooling medium, all the media that appear appropriate to one skilled in the art will be used, including in particular various liquid media, but especially advantageously gaseous media; in an open cooling system, air is preferably used as the cooling medium.

As the pressure source, various means that appear appropriate to one skilled in the art will be employed, such as a pressure reservoir, formed by a removable or fixedly installed pressure vessel, which is filled with a pressure medium continuously or discontinuously by an internal and/or external pressure generator. However, if the battery cooler itself includes at least one pump, then especially flexible operation can be assured. The term “pump” should be understood in this context to mean in particular a machine that is distinguished by encapsulation of a cooling medium, so as then to displace this medium at elevated pressure into a pressure conduit, and/or in particular a machine, by means of which a pressure in the cooling medium of more than 100 mbar, advantageously more than 200 mbar, and especially advantageously more than 300 mbar, can be established.

In principle, all kinds of pumps that appear appropriate to one skilled in the art are conceivable, such as centrifugal pumps, jet pumps, and vacuum pumps, but especially advantageously positive-displacement pumps, such as piston pumps and diaphragm pumps in particular, which can be integrated in a structurally simple, space-saving and economical way.

In a further feature, it is proposed that the pump is intended for a pulsed mode of operation, as a result of which eddies or turbulent flows that reinforce the cooling can be achieved without additional expense.

In addition or alternatively, at least one flow guide means for generating eddies or turbulent flows in the region of at least one battery unit may be provided, to improve heat transfer. The term “flow guide means” should be understood in particular as a means whose shaping is at least essentially determined by its flow guide function.

The provisions of the invention can be employed in all devices that appear appropriate to one skilled in the art, but especially advantageously in hybrid drive units for hybrid vehicles, which because of their high energy requirements often have battery packs with a packing density, and/or especially advantageously in hand power tools, which because of their requirements for a compact structure and low weight have battery packs with a high packing density.

In a system with a machine and a removable battery pack, the battery cooler can be integrated partially or entirely into the machine and/or the battery pack.

Further advantages will become apparent from the ensuing description of the drawings. In the drawings, exemplary embodiments of the invention are shown. The drawing, description and claims include numerous characteristics in combination. One skilled in the art will expediently consider the characteristics individually as well and put them together to make further appropriate combinations.

### BRIEF DESCRIPTION OF THE DRAWINGS

FIG. 1 shows a hand power tool with a battery cooler in accordance with the present invention;

FIG. 2 is a schematic sectional view of the battery cooler taken along the line II-II in FIG. 1; and

FIG. 3 shows a detail of a charger with a battery cooler in accordance with the present invention.

### DESCRIPTION OF THE PREFERRED EMBODIMENTS

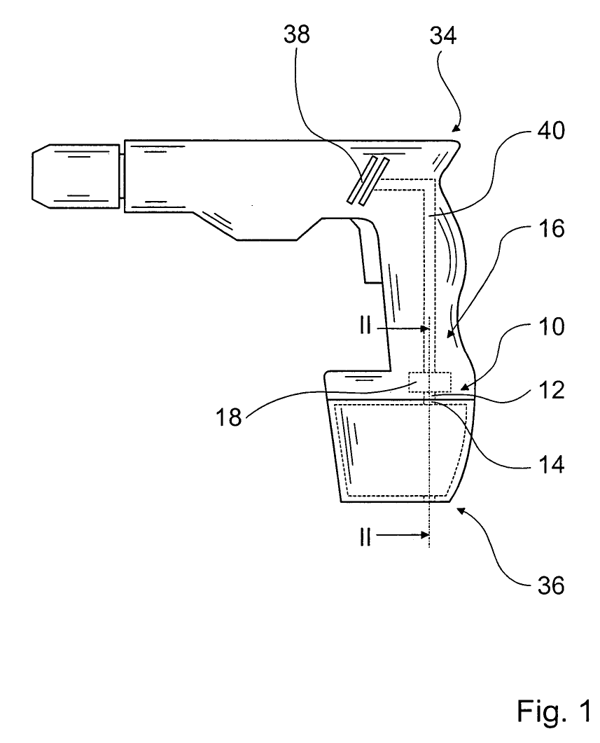

FIG. 1 shows a hand power tool 34, embodied as a battery-operated screwdriver, which has a replaceable battery pack 36 that includes a battery cooler with a flow guidance unit 10.

The battery cooler includes a pump 18, formed by a positive-displacement machine, which is located in a hand power tool housing, and specifically in a housing part of the hand power tool 34 that forms a handle.

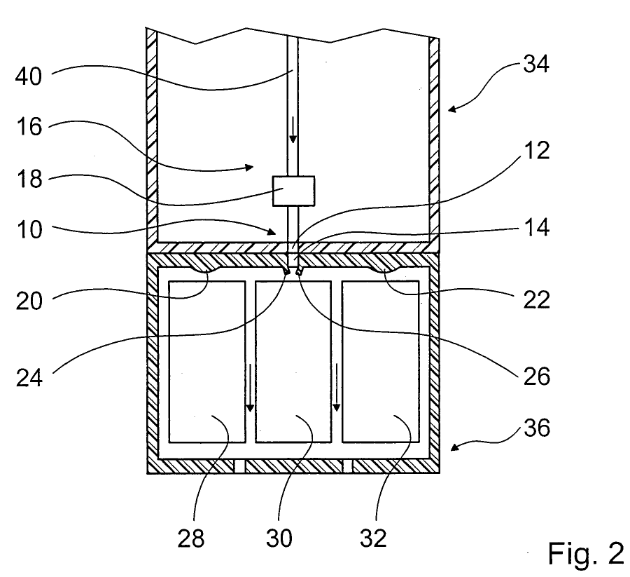

The flow guidance unit 10 includes two pressure conduits 12, 14, specifically a first pressure conduit 12, which extends inside the hand power tool housing from the pump 18 of the battery cooler to a housing wall of the hand power tool 34 and through the housing wall, and a second pressure conduit 14, which extends through a housing wall of the battery pack 36 into a housing of the battery pack 36 and from there branches out through a plurality of battery units 28, 30, 32 and then passes through a housing wall, forming a bottom part, of the battery pack 36 and extends out of the housing of the battery pack 36 (FIGS. 1 and 2). The battery cooler includes an open cooling system 16, and specifically, fresh air is aspirated from the environment as a cooling medium by the pump 18 via air slits 38 and a supply conduit 40, and this fresh air, after absorbing heat in the battery pack 36, is fed back outside to the environment.

In operation, the pump 18 builds up a pressure of approximately 300 mbar, with which the cooling medium formed by fresh air is pumped or pressed through the battery pack 36. The pump 18 is operated in pulsed fashion in the process; that is, the cooling medium is pumped in pulsed fashion through the battery pack 36, creating a turbulent flow inside the battery pack 36 that promotes a heat transfer. In addition, flow guide means 20, 22, 24, 26, formed integrally onto the battery pack housing, are located inside the battery pack 36 for generating eddies in the region of the battery units 28, 30, 32.

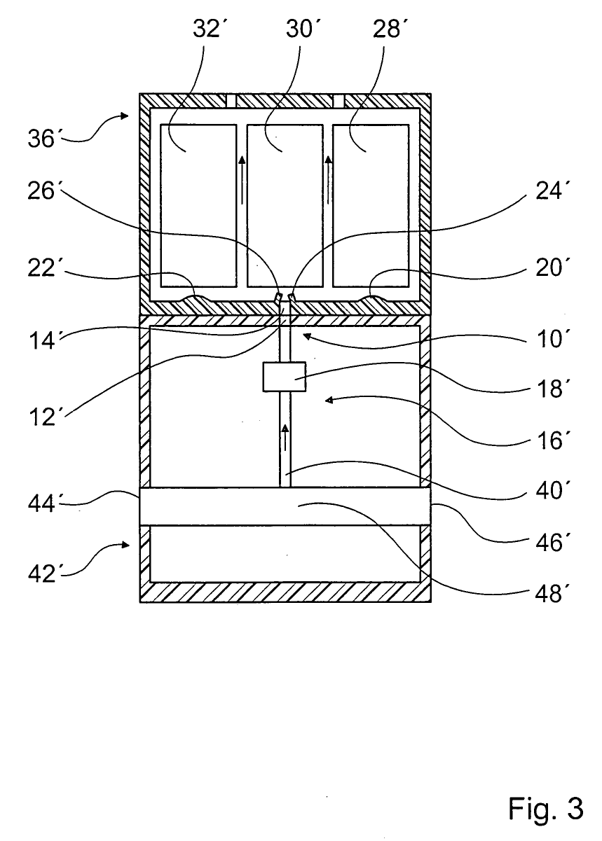

FIG. 3 shows a further exemplary embodiment. Essentially, elements that remain the same are all identified by the same reference numerals, but to distinguish among the exemplary embodiments, a prime is added to the reference numerals for the exemplary embodiment in FIG. 3. In addition, reference may be made to the description of the exemplary embodiment in FIGS. 1 and 2 for characteristics and functions that remain the same. The ensuing description is limited essentially to the differences from the exemplary embodiment in FIGS. 1 and 2.

FIG. 3 shows a charger 42′ for charging a battery pack 36′ that can be positioned in it and that includes a battery cooler having a flow guidance unit 10′.

The battery cooler includes a pump 18′, formed by a positive-displacement machine and located in a charger housing.

The flow guidance unit 10′ includes two pressure conduits 12′, 14′, specifically a first pressure conduit 12′, which extends inside the charger 42′ from the pump 18′ of the battery cooler to a housing wall of the charger 42′ and through the housing wall, and a second pressure conduit 14′, which extends through a housing wall of the battery pack 36′ into a housing of the battery pack 36′ from which it branches out through a plurality of battery units 28′, 30′, 32′ and then passes through a housing wall, forming a bottom part, of the battery pack 36′ and extends out of the housing of the battery pack 36′. The battery cooler includes an open cooling system 16′, and specifically, fresh air is aspirated from the environment as a cooling medium by the pump 18′ via intake openings 44′, 46′, a transverse conduit 48′, and a supply conduit 40′, and this fresh air, after absorbing heat in the battery pack 36′, is fed back outside to the environment.

It will be understood that each of the elements described above, or two or more together, may also find a useful application in other types of constructions differing from the types described above.

While the invention has been illustrated and described as embodied in a battery cooler, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims.

1. A battery cooler, comprising a flow guidance unit, said flow guidance unit including at least one pressure conduit.

2. A battery cooler as defined in claim 1, wherein the battery cooler has an open cooling system.

3. A battery cooler as defined in claim 1; and further comprising at least one pump for pumping a cooling medium in said at least one pressure conduit.

4. A battery cooler as defined in claim 3, wherein said pump is configured as a positive-displacement machine.

5. A battery cooler as defined in claim 3, wherein said pump is configured for generating a pressure of more than 100 mbar.

6. A battery cooler as defined in claim 3, wherein said pump is configured as a pump having a pulse mode of operation.

7. A battery cooler as defined in claim 1; and further comprising at least one battery unit; and at least one flow guide means for generating eddies in a region of said at least one battery unit.

8. A hand power tool, comprising a battery cooler including a flow guidance unit, said flow guidance unit including at least one pressure conduit.

9. A charger, comprising a battery cooler including a flow guidance unit, said flow guidance unit including at least one pressure conduit.

10. A hybrid drive unit, comprising a battery cooler including a flow guidance unit, said flow guidance unit including at least one pressure conduit.

11. A battery pack, comprising a battery cooler including a flow guidance unit, said flow guidance unit including at least one pressure conduit.
